(19) United States
(12) Patent Application Publication
(10) Pub. No.: US 2016/0115583 A1
(43) Pub. Date: Apr. 28, 2016

(54) DEVICE AND METHOD FOR VACUUM EVAPORATING

(71) Applicant: SAMSUNG ELECTRONICS CO., LTD., Suwon-si (KR)

(72) Inventors: JI-HO UH, Seongnam-si (KR); Jun-Sung Lee, Seongnam-si (KR)

(21) Appl. No.: 14/726,257

(22) Filed: May 29, 2015

(30) Foreign Application Priority Data
Oct. 27, 2014 (KR) 10-2014-0146286

(51) Int. Cl. C23C 14/24; C23C 14/54

(52) U.S. Cl. CPC C23C 14/243; C23C 14/24; C23C 14/54

(57) ABSTRACT

A device for vacuum evaporating includes a thermal evaporation module that generates vapor in a vacuum chamber through a circular opening by heating a vapor evaporation material accommodated therein. A moving stage is positioned in an atmospheric area separated from the vacuum chamber and adjusts a position of the thermal evaporation module under the thermal evaporation module. A sealing part is combined with the thermal evaporation module to isolate the vacuum chamber and the atmospheric area from each other and maintain a vacuum state of the vacuum chamber while surrounding the thermal evaporation module and permitting movement of the thermal evaporation module.

### CROSS-REFERENCE TO RELATED APPLICATION

This application claims under 35 U.S.C. 119 priority to and the benefit of Korean Patent Application No. 10-2014-0146286 filed on Oct. 27, 2014 in the Korean Intellectual Property Office, the entire contents of which are incorporated by reference herein.

### BACKGROUND

1. Technical Field

The present inventive concept relates to a vacuum evaporating device and method for vacuum evaporating.

2. Description of the Related Art

An organic light emitting diode (OLED) is a self-emitting device that emits light in such a manner that current flows through a phosphorescent organic compound. A television using an OLED can be driven with a low voltage and can be manufactured as a thin film type. The television using an OLED has a wide viewing angle and a quick response speed, so that a screen of the television using an OLED can be viewed right next thereto without deterioration in the picture quality and no afterimage remains on the screen, unlike a television using a liquid crystal display (LCD). A small-sized screen of the television using an OLED can provide higher picture quality than a screen of the television using the LCD, and can be manufactured in a simplified manufacturing process while reducing the manufacturing cost.

In the television using the OLED, however, an organic material and a cathode may not be formed by other than vacuum thermal evaporation due to a probability of lowering durability of an organic material evaporated layer.

### SUMMARY

The present inventive concept provides a device for vacuum evaporating, which can improve uniformity of a vapor evaporation layer during thermal evaporation.

The present inventive concept also provides a method for vacuum evaporating, which can improve uniformity of a vapor evaporation layer during thermal evaporation.

According to an aspect of the present inventive concept, there is provided a device for vacuum evaporating, the device including a thermal evaporation module generating vapor in a vacuum chamber through a circular opening by heating a vapor evaporation material accommodated therein, a moving stage positioned in an atmospheric area separated from the vacuum chamber and adjusting a position of the thermal evaporation module under the thermal evaporation module, and a sealing part combined with the thermal evaporation module to isolate the vacuum chamber and the atmospheric area from each other and maintaining a vacuum state of the vacuum chamber while surrounding the thermal evaporation module and permitting movement of the thermal evaporation module.

The thermal evaporation module includes a crucible accommodating the vapor evaporation material and including the circular opening, a heater heating the crucible from the outside of the crucible and a cooler surrounding the heater and preventing heat derived from the heater from spreading.

The vacuum chamber includes a source hole opened to allow at least a portion of the thermal evaporation module to pass therethrough to be positioned in the vacuum chamber, and the sealing part includes a protruding disk protruding on an outer wall of the thermal evaporation module, a bellows surrounding the thermal evaporation module between an edge outer wall of the source hole of the vacuum chamber and the protruding disk and maintaining a vacuum state of the thermal evaporation module while permitting position movement of the vacuum chamber and an o-ring sealing a portion between the bellows and the edge outer wall of the source hole or between the bellows and the protruding disk.

The source hole has a size larger than that of a horizontal section of the thermal evaporation module, and a horizontal movement range of the thermal evaporation module is limited by the size of the source hole.

The moving stage moves the thermal evaporation module in three directions orthogonal to one another.

The thermal evaporation module includes first and second thermal evaporation modules separated from each other and positions of the first and second thermal evaporation modules are moved independently of each other.

According to another aspect of the present inventive concept, there is provided a device for vacuum evaporating, the device including a vacuum chamber which a glass panel passes and which includes a plurality of source holes, a plurality of point sources thermally evaporating an organic layer or an inorganic layer on one surface of the glass panel and configured to be movable, and a sealing part positioned between the point sources and an outer wall of the vacuum chamber and maintaining the inside of the vacuum chamber at a vacuum state while permitting movement of the point sources.

The plurality of source holes are aligned in a direction perpendicular to a traveling direction of the glass panel.

Each of the source holes has a larger size than a horizontal section of each of the point sources and a movement range of each of the point sources is confined by the size of the source hole.

The point sources are used in depositing a cathode on one surface of the glass panel.

The glass panel includes first and second glass panel sequentially passing the vacuum chamber, the device further including a controller readjusting positions of the point sources based upon the uniformity in the thickness of the cathode deposited on the first glass panel, and the point sources uniformly deposit the cathode on one surface of the second glass panel while the second glass panel passes at the readjusted positions of the point sources.

The plurality of point sources move in three directions orthogonal to one another to be aligned to uniformly deposit the cathode.

The cathode includes aluminum (Al).

The source holes and the point sources correspond to each other in a one-to-one relationship.

The point sources deposit an organic layer containing carbon on one surface of the glass panel.

The sealing part includes a protruding disk protruding on an outer wall of each of the point sources, a bellows surrounding the thermal evaporation module between an edge outer wall of the vacuum chamber and the protruding disk and maintaining a vacuum state of the thermal evaporation module while permitting position movement of the vacuum chamber and an o-ring sealing a portion between the bellows and the edge outer wall of the source hole or between the bellows and the protruding disk.

According to still another aspect of the present inventive concept, there is provided a device for vacuum evaporating, the device including a vacuum chamber in which a panel moves in one direction, a plurality of point sources positioned within the vacuum chamber and thermally evaporating a thin film on one surface of the panel at fixed positions, an inspector inspecting a thickness of the thin film, and a controller receiving the thickness from the inspector and readjusting positions of the plurality of point sources.

When the positions of the plurality of point sources are realigned, the plurality of point sources are moved by the same displacement.

The inspector inspects uniformity of the thin film and the controller readjusts the positions of the plurality of point sources to deposit the thin film having uniformity in thickness.

The controller receives information on a profile of the thin film and readjusts the positions of the plurality of point sources to deposit the thin film having the same profile with the received profile.

### BRIEF DESCRIPTION OF THE DRAWINGS

The above and other features and advantages of the present inventive concept will become more apparent by the description of exemplary embodiments thereof with reference to the attached drawings in which:

FIG. 1 is a side section view illustrating a vapor evaporating device according to an embodiment of the present inventive concept;

FIG. 2 is a plan view illustrating the vapor evaporating device according to an embodiment of the present inventive concept;

FIG. 3 is a front section view illustrating the vapor evaporating device according to an embodiment of the present inventive concept;

FIG. 4 is a section view for explaining a point source of the vapor evaporating device according to an embodiment of the present inventive concept;

FIG. 5 is a graph illustrating a simulation result of thicknesses of a thin film evaporated using the vapor evaporating device according to an embodiment of the present inventive concept;

FIG. 6 is a graph illustrating comparison results of simulated values and actually measured values of thicknesses of thin films evaporated by the vapor evaporating device according to an embodiment of the present inventive concept;

FIG. 7 is a block diagram illustrating the vapor evaporating device according to an embodiment of the present inventive concept;

FIG. 8 is a plan view illustrating position movement of the vapor evaporating device according to an embodiment of the present inventive concept;

FIG. 9 is a front section view illustrating position movement of the vapor evaporating device according to an embodiment of the present inventive concept;

FIG. 10 is a graph illustrating a simulation result of thicknesses of a thin film evaporated using the vapor evaporating device according to an embodiment of the present inventive concept;

FIG. 11 is a graph illustrating an actual measurement result of thicknesses of a thin film evaporated using the vapor evaporating device according to an embodiment of the present inventive concept;

FIG. 12 is a graph illustrating a correction result of thicknesses of a thin film by position movement of the vapor evaporating device according to an embodiment of the present inventive concept;

FIG. 13 is a plan view illustrating a vapor evaporating device according to an embodiment of the present inventive concept;

FIG. 14 is a plan view illustrating position movement of the vapor evaporating device according to an embodiment of the present inventive concept;

FIG. 15 is a block diagram illustrating a vapor evaporating device according to an embodiment of the present inventive concept;

FIG. 16 is a plan view illustrating a vapor evaporating device according to an embodiment of the present inventive concept;

FIG. 17 is a plan view illustrating position movement of the vapor evaporating device according to an embodiment of the present inventive concept; and

FIG. 18 is a flowchart illustrating a vacuum evaporating method according to an embodiment of the present inventive concept.

### DETAILED DESCRIPTION

The present inventive concept may be embodied in many different forms and should not be construed as being limited to the embodiments set forth herein. Rather, these embodiments are provided so that this disclosure will be thorough and complete and will fully convey the concept of the inventive concept to those skilled in the art, and the present inventive concept will only be defined by the appended claims. Like reference numerals refer to like elements throughout the specification.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being “on”, “connected to” or “coupled to” another element or layer, it can be directly on, connected or coupled to the other element or layer or intervening elements or layers may be present. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concept.

Spatially relative teams, such as “beneath”, “below”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Embodiments are described herein with reference to cross-section illustrations that are schematic illustrations of idealized embodiments (and intermediate structures). As such, variations from the shapes of the illustrations as a result, for example, of manufacturing techniques and/or tolerances, are to be expected. Thus, these embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein have the same meaning as commonly understood by one of ordinary skill in the art to which the present inventive concept belongs. It will be further understood that terms, such as those defined in commonly used dictionaries, should be interpreted as having a meaning that is consistent with their meaning in the context of the relevant art and this specification and will not be interpreted in an idealized or overly formal sense unless expressly so defined herein.

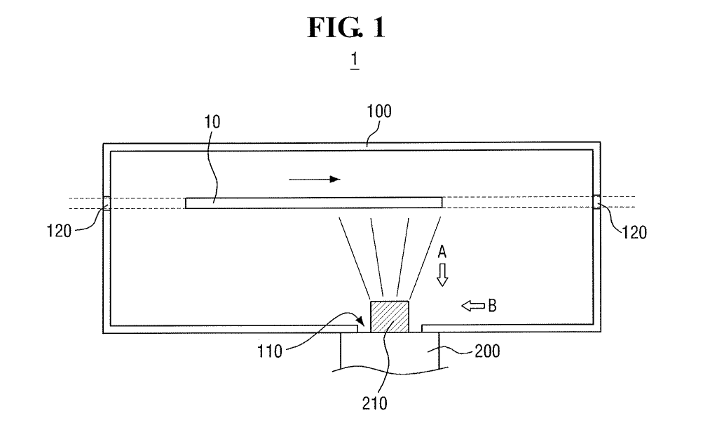

Hereinafter, a vapor evaporating device according to an embodiment of the present inventive concept will be described with reference to FIGS. 1 to 13. FIG. 1 is a side section view illustrating a vapor evaporating device 1 according to an embodiment of the present inventive concept.

Referring to FIG. 1, the vacuum evaporating device 1 according to an embodiment of the present inventive concept includes a vacuum chamber 100 and a point source 200.

The vacuum chamber 100 may be a closed chamber isolated from the outside. That is to say, the vacuum chamber 100 may be a receiving space having an internal vacuum, unlike the ambient atmosphere. A vacuum pressure of the vacuum chamber 100 may be slightly higher than that of the universe. For example, the vacuum pressure of the vacuum chamber 100 may be approximately 10⁻⁵ Pa, but aspects of the present inventive concept are not limited thereto.

A panel 10 may travel in one direction within the vacuum chamber 100. An organic material thin film or an inorganic material thin film may be deposited on the panel 10 within the vacuum chamber 100. That is to say, the depositing of the organic material thin film or the inorganic material thin film may be performed under a vacuum condition.

The panel 10 may be in the shape of a plate having relatively thin lateral surfaces and opposite surfaces having a relatively wide area. The opposite surfaces having a relatively wide area may be rectangular, but aspects of the present inventive concept are not limited thereto. The panel 10 may be used as a panel of a television or a display device.

The panel 10 may have an organic material thin film deposited thereon in the vacuum chamber 100 to represent a color. The organic material thin film is a carbon-containing organic material layer.

After depositing the organic material thin film, a cathode thin film may be uniformly deposited. The cathode may include, for example, aluminum (Al).

The panel 10 may generally include glass, but aspects of the present inventive concept are not limited thereto. When the panel 10 includes glass, it may have rigidity so as not be easily bendable. However, the panel 10 may include a flexible material, instead of glass. In an embodiment, the panel 10 may be a flexible panel that is curved or bendable.

The vacuum chamber 100 may include a source hole 110 and a sliding door 120.

The source hole 110 may be formed under the vacuum chamber 100, but aspects of the present inventive concept are not limited thereto. In an exemplary embodiment shown in FIG. 1, the source hole 110 is formed under the vacuum chamber 100, and when the panel 10 travels in one direction in a line, the point source 200 to be described later may form a thin film on one surface, that is, bottom surface, of the panel 10 through thermal evaporation. However, the source hole 110 may be positioned on a lateral surface or a top surface of the vacuum chamber 100, rather than the bottom surface. In this case, the position of the panel 10 may also vary. During the thermal evaporation, the point source 200 is generally positioned under the panel 10.

The point source 200 may be positioned in the source hole 110. The source hole 110 may be an opening configured to allow the point source 200 to deposit a thin film on the panel 10. The point source 200 may be positioned in the source hole 110 in a state in which at least one of the point source 200 passes through the source hole 110, but aspects of the present inventive concept are not limited thereto. The point source 200 and the source hole 110 are not limited in view of vertical positions so long as the point source 200 can deposit a thin film on one surface of the panel 10 through the source hole 110.

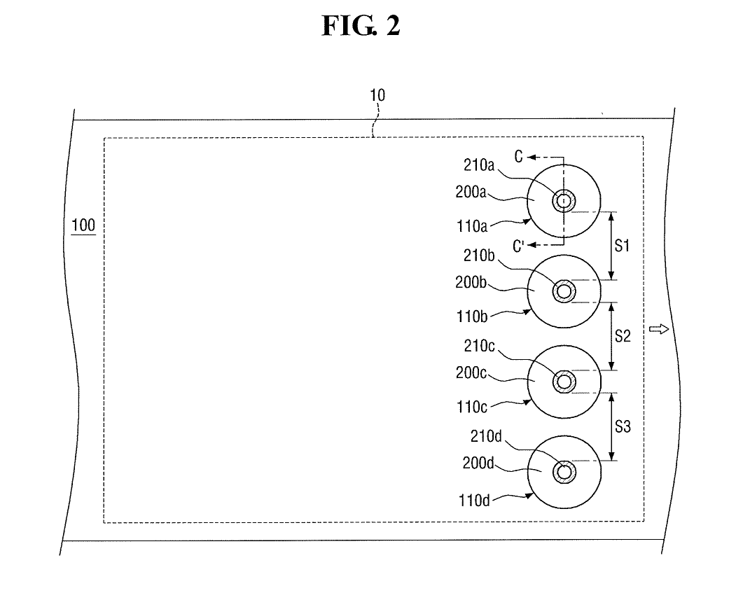

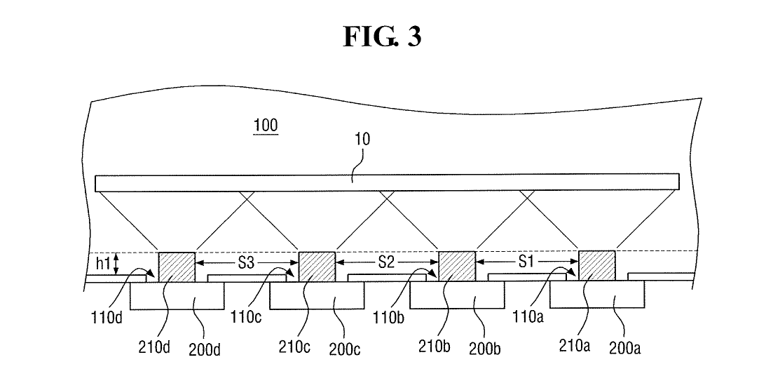

The single source hole 110 of the view depicted in FIG. 1 may be a plurality of source holes, as seen in FIGS. 2 and 3. The source hole 110 and the point source 200 may correspond to each other in a one-to-one relationship. That is to say, each of the plurality of point sources 200 may be positioned to correspond to one of the plurality of source holes 110. While the source hole 110 is an opening, in order to maintain the vacuum chamber 100 at a vacuum state, a device may be additionally required to maintain the vacuum state at a portion where the source hole 110 and the point source 200 are coupled to each other.

The sliding door 120 is an entrance door of the panel 10. The sliding door 120 is normally closed to maintain a vacuum state. The sliding door 120 may be configured to be opened when the panel 10 enters the vacuum chamber 100 from the outside of the vacuum chamber 100. As the panel 10 enters, the sliding door 120 may be pushed by an entering part of the panel 10 to allow the sliding door 120 to be opened. The sliding door 120 may include corners separated from sidewalls of the vacuum chamber 100. While the sliding door 120 is connected to the sidewalls of the vacuum chamber 100 at opposite sides of the corners, the sliding door 120 may include a corner having a rotary shaft about which the sliding door 120 can be rotated.

The sliding door 120 may be formed on facing sidewalls of the vacuum chamber 100. Therefore, the panel 10 may enter the sliding door 120 positioned on one sidewall of the vacuum chamber 100 and may exit from the sliding door 120 positioned on the other sidewall of the vacuum chamber 100.

The sliding door 120 may have a size equal to a thickness of the entering panel 10. Therefore, even when the sliding door 120 enters the vacuum chamber 100, the inside of the vacuum chamber 100 may be maintained at a vacuum state.

The point source 200 may deposit an organic or inorganic material thin film on the panel 10 at its fixed position. That is to say, as the panel 10 travels in one direction, the point source 200 may entirely deposit a thin film on one surface of the panel 10 at its fixed position.

The point source 200 may be positioned in the source hole 110. The source hole 110 may include a plurality of sources holes and the point source 200 may also include a plurality of point source so as to correspond thereto. That is to say, the point sources 200 and the source holes 110 may correspond to each other in a one-to-one relationship, but aspects of the present inventive concept are not limited thereto.

The point source 200 may deposit a thin film upwardly from a lower portion of the vacuum chamber 100 through the source hole 110. The thin film may be deposited on the bottom surface of the panel 10, as shown. In view of the thermal evaporation principle in which a vapor evaporation material is heated and vaporized for evaporation, it is difficult to control a thickness of the thin film positioned on a top surface or a lateral surface, rather than the bottom surface, of the panel 10. However, the position of the point source 200 is not limited.

The point source 200 may include a thermal evaporation module 210. The thermal evaporation module 210 contains the vapor evaporation material. The thermal evaporation module 210 may include a top opening to allow the heated and vaporized vapor evaporation material to be upwardly exhausted.

FIG. 2 is a plan view illustrating the vapor evaporating device 1 according to an embodiment of the present inventive concept. FIG. 2 is a diagram of the vapor evaporating device according to an embodiment of the present inventive concept, viewed in a direction ‘A’ of FIG. 1. Here, the panel 10 is indicated by a dotted line to represent an overlapping position.

Referring to FIG. 2, the source hole 110 in FIG. 1 includes a plurality of source holes, which may be aligned each other. The source hole 110 in FIG. 1 may include first source hole 110a, second source hole 110b, third source hole 110c and fourth source hole 110d. The plurality of source holes 110 may be aligned in a direction perpendicular to a direction, as indicated by the arrow in FIG. 2, in which the panel 10 travels. According to the alignment of the source holes 110, a thickness of the thin film deposited on one surface of the panel 10 may be controlled.

In FIG. 2, the source hole 110 including 4 source holes is illustrated, which is, however, provided only for illustration. There is no particular limit in the number of source holes 110.

The point sources 200 may be positioned in the source holes 110. The point sources 200 may correspond to the source holes 110 in a one-to-one relationship. Since the source holes 110 are aligned, the point sources 200 may also be aligned, as shown. However, the alignment of the point sources 200 may be modified in various manners, unlike the fixed alignment of the source holes 110.

Since multiple point sources 200 may be provided, they may be spaced apart from one another. A first thermal evaporation module 210a of a first point source 200a and a second thermal evaporation module 210b of a second point source 200b may be spaced a first distance S1 apart from each other. A second thermal evaporation module 210b of a second point source 200b and a third thermal evaporation module 210c of a third point source 200c may be spaced a second distance S2 apart from each other. A third thermal evaporation module 210c of a third point source 200c and a fourth thermal evaporation module 210d of a fourth point source 200d may be spaced a third distance S3 apart from each other.

The first distance S1 to the third distance S3 may be equal to or different from one another. A thin film having uniformity can be deposited when the first distance S1 to the third distance S3 can be equal to each other. However, the first distance S1 to the third distance S3 may be adjusted according to various external parameters.

FIG. 3 is a front section view illustrating the vapor evaporating device according to an embodiment of the present inventive concept.

Referring to FIG. 3, the vapor evaporating device 1 according to an embodiment of the present inventive concept may include a plurality of point sources 200, that is, first to fourth point sources 200a, 200b, 200c, 200d, and a thermal evaporation module 210 of each of the plurality of point sources 200 may have a constant height. Referring to FIG. 3, each of the first to fourth thermal evaporation modules 210a, 210b, 210c, 210d may have a first height h1. The first height h1 may mean a distance between a top surface of the thermal evaporation module 210 and a bottom surface of the vacuum chamber 100.

Referring to FIG. 3, all of the first thermal evaporation module 210a to the fourth thermal evaporation module 210d may have the same height, that is, the first height h1. However, the first height h1 may be readjusted according to various external parameters.

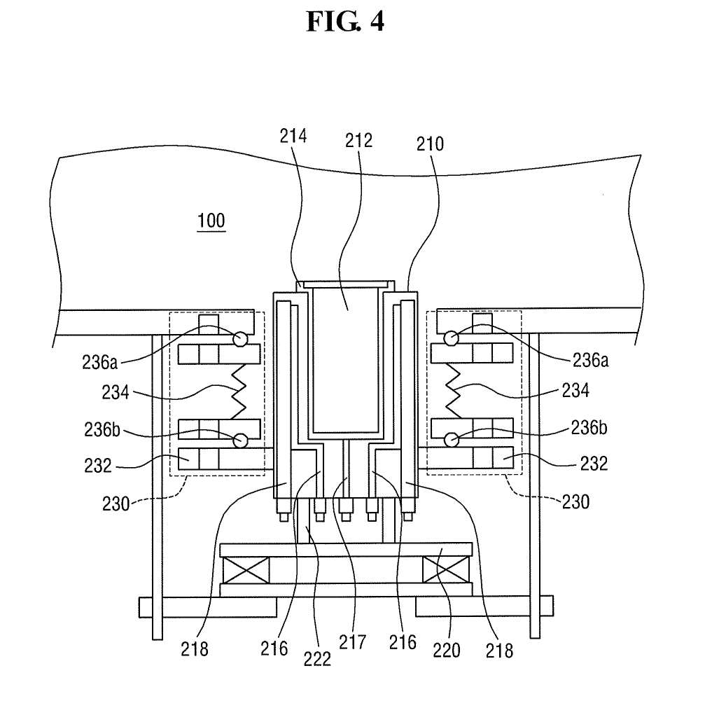

FIG. 4 is a section view for explaining in more detail a point source of the vapor evaporating device according to an embodiment of the present inventive concept.

Referring to FIG. 4, in the vapor evaporating device 1 according to an embodiment of the present inventive concept, the point source 200 may include a thermal evaporation module 210, a moving stage 220 and a sealing part 230.

The thermal evaporation module 210 contains a vapor evaporation material and heats the vapor evaporation material at a high temperature to be vaporized. The thermal evaporation module 210 may form a thin film on one surface of the panel 10 using the resulting vapor.

The thermal evaporation module 210 may have a position where it passes through the source hole 110. The thermal evaporation module 210 may be spaced apart from sidewalls of the source hole 110. Therefore, the thermal evaporation module 210 may move within a range in which it comes into contact with the source hole 110.

The thermal evaporation module 210 includes an internal crucible 212, an external crucible 214, a heater 216, a temperature sensor 217 and a cooler 218.

The internal crucible 212 may have a space to receive the vapor evaporation material. The internal crucible 212 may include a top opening to allow the vapor evaporation material that is heated and vaporized to be upwardly exhausted to the outside. The internal crucible 212 may be shaped of a crucible without a step difference, as shown. However, the invention does not particularly limit the shape of the internal crucible 212 to that illustrated herein so long as it is configured to receive the vapor evaporation material and to allow the vaporized material to be exhausted.

The external crucible 214 may surround the internal crucible 212 without a gap. The internal crucible 212 and the external crucible 214 may constitute a dual crucible. The external crucible 214 may be provided to improve durability and heat resistance of the internal crucible 212 while transferring a temperature to the internal crucible 212. Alternatively, the external crucible 214 and the internal crucible 212 may be replaced by a single crucible.

The heater 216 may heat the external crucible 214 and the internal crucible 212 from the outside of the external crucible 214. The heater 216 may heat the internal crucible 212 at a temperature high enough to vaporize the vapor evaporation material contained in the internal crucible 212. The temperature may be, for example, approximately 1000° C., but aspects of the present inventive concept are not limited thereto.

The temperature of the heater 216 may be controlled. The extent of vaporization of the vapor evaporation material may vary according to the temperature of the heater, which may affect the output of the point source 200.

The temperature sensor 217 may measure a temperature of an internal crucible 212 or an external crucible 214. The temperature sensor 217 may notify a user of data of the temperature of the heater 216 of the point source 200. The user may determine whether to raise or lower the temperature of the heater 216 based upon the data of the temperature, sensed by the temperature sensor 217. Alternatively, the heater 216 may be automatically driven by the temperature sensor 217. The temperature sensor 217a may receive a target temperature and may control driving of the heater 216 until the target temperature is reached.

The cooler 218 may cool heat from the high temperature raised by the heater 216. The cooler 218 may prevent the heat derived from the heater 216 from spreading. The thermal evaporation module 210 may use a heat resistant component because it should withstand a high temperature. Therefore, the thermal evaporation module 210 itself may well withstand a high temperature. However, if the high temperature is transferred to a component in contact with the external surface of the thermal evaporation module 210, the product may be damaged. Accordingly, in order to prevent the high temperature from being transferred, the cooler 218 may lower the temperature.

The operation of the cooler 218 may also be controlled. That is to say, the temperature sensor 217 may notify the user of the temperature and the user may drive the cooler 218 to control the temperature. Alternatively, the driving of the cooler 218 may also be automatically performed by the temperature sensor 217. The temperature sensor 217 may receive a target temperature and may control the driving of the cooler 218 until the target temperature is reached.

The moving stage 220 may move the thermal evaporation module 210. The moving stage 220 may move the thermal evaporation module 210 in three directions orthogonal to one another. The three directions may mean x-y-z directions on the orthogonal coordinate system. If the thermal evaporation module 210 is moved by the moving stage 220, distances and positions of the point sources 200 may be readjusted.

The position of the thermal evaporation module 210 moved by the moving stage 220 may be confined by sidewalls of the source holes 110. The moving stage 220 may be moved to a range in which the thermal evaporation module 210 comes into contact with the sidewalls of the source hole 110. The movement range of the thermal evaporation module 210 may not deviate from the source hole 110.

The moving stage 220 may include a supporter 222. The supporter 222 may be positioned between the moving stage 220 and the thermal evaporation module 210. The supporter 222 may support the thermal evaporation module 210 on the moving stage 220. The supporter 222 may tightly couple the thermal evaporation module 210 and the moving stage 220 to each other.

The supporter 222 may allow a bottom surface of the thermal evaporation module 210 to be spaced apart from a top surface of the moving stage 220. Accordingly, a power supply and a signal line may be connected to the temperature sensor 217, the heater 216 and the cooler 218 through the bottom surface of the thermal evaporation module 210.

The sealing part 230 may isolate a vacuum area and an atmospheric area from each other by the vacuum chamber 100. The sealing part 230 may maintain a vacuum state of the vacuum chamber 100 while permitting movement of the thermal evaporation module 210.

The temperature sensor 217, the heater 216 and the cooler 218 of the thermal evaporation module 210 and the moving stage 220 have many limitations in use under vacuum due to outgassing or leak. The moving of the thermal evaporation module 210 in the vacuum area is difficult to achieve because components capable of operating in vacuum should be used. Therefore, in the vapor evaporating device 1 according to an embodiment of the present inventive concept, a connection part between the moving stage 220 and the thermal evaporation module 210, the temperature sensor 217, the heater 216 and the cooler 218 may be provided in the atmospheric area, that is, in an area having an atmospheric pressure, not a vacuum. Therefore, the sealing part 230 is configured to isolate the vacuum chamber and the atmospheric area from each other while permitting movement of the thermal evaporation module 210.

The sealing part 230 includes a protruding disk 232, a bellows 234 and an o-ring 236.

The protruding disk 232 may be attached to an outer wall of the thermal evaporation module 210. The protruding disk 232 may be formed to protrude beyond the outer wall of the thermal evaporation module 210. The protruding disk 232 may be formed to surround the outer wall of the thermal evaporation module 210. The protruding disk 232 may be closely adhered to the outer wall of the thermal evaporation module 210. There may be no gap between the protruding disk 232 and the outer wall of the thermal evaporation module 210. This is for the purpose of isolating the vacuum area from the atmospheric area.

The protruding disk 232 may also isolate the bellows 234 and the vacuum area and the atmospheric area through the o-ring 236.

The bellows 234 may be shaped of a corrugated pipe permitting horizontal movement. Since the bellows 234 is a corrugated pipe, it also permits vertical movement of the thermal evaporation module 210. However, the thermal evaporation module 210 may not move beyond the maximum spacing of the bellows 234. Since the thermal evaporation module 210 should not make contact with the panel 10, the maximum spacing of the bellows 234 may be in a range in which the panel 10 and the thermal evaporation module 210 contact with each other.

Therefore, even if the thermal evaporation module 210 is moved by the moving stage 220, the vacuum state of the vacuum chamber 100 may be maintained through the bellows 234.

The o-ring 236 may include an upper o-ring 236a and a lower o-ring 236b, but aspects of the present inventive concept are not limited thereto. The -ring 236 may include only one of the upper o-ring 236a and the lower o-ring 236b.

The upper o-ring 236a may shield a gap between a bottom wall of the vacuum chamber 100 and the bellows 234. The upper o-ring 236a may be a circumferential flexible member and may prevent the air from moving between a gap between components.

The upper o-ring 236a may be positioned along the edge of the source hole 110. The upper o-ring 236a may be positioned between a bottom surface of the outer wall of the vacuum chamber 100, forming a bottom of the vacuum chamber 100, and a top surface of an upper portion of the bellows 234. Accordingly, the vacuum area and the atmospheric area may be isolated from each other. Since the upper portion of the bellows 234 is not moved, it may be tightly coupled to the bottom wall of the vacuum chamber 100 fixed together.

The lower o-ring 236b may shield a gap between a top surface of the protruding disk 232 and the bellows 234. The lower o-ring 236b may be a circumferential flexible member and may prevent the air from moving between a gap between components.

The lower o-ring 236b may be positioned along the edge of the protruding disk 232. The lower o-ring 236b may be positioned between a top surface of the protruding disk 232 and a bottom surface of a lower portion of the bellows 234. Accordingly, the vacuum area and the atmospheric area may be isolated from each other. Since the lower portion of the bellows 234 is moved together with the thermal evaporation module 210, it may be tightly coupled to the top surface of the protruding disk 232 moved together.

In the vapor evaporating device 1 according to an embodiment of the present inventive concept, the thermal evaporation module may move in three directions orthogonal with one another while maintaining the vacuum chamber 100 at a vacuum state.

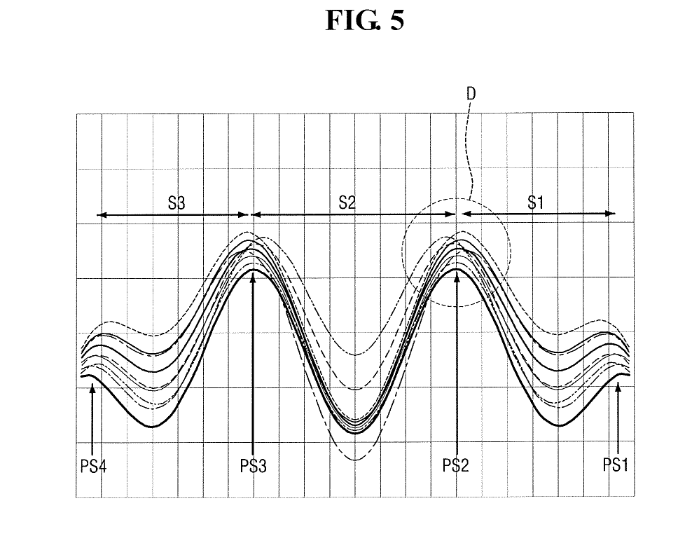

FIG. 5 is a graph illustrating a simulation result of thicknesses of a thin film evaporated using the vapor evaporating device according to an embodiment of the present inventive concept. Here, the horizontal axis is perpendicular to a direction in which the panel 10 travels and the vertical axis indicates the thickness of a thin film.

Referring to FIG. 5, thicknesses of a thin film deposited according to positions of the point sources 200 spaced a first distance S1 to a third distance S3 apart from one another may be slightly different from one another. A horizontal position of a first point source 200a is represented by PS1. A horizontal position of a second point source 200b is represented by PS2. A horizontal position of a third point source 200c is represented by PS3. A horizontal position of a fourth point source 200d is represented by PS4. The respective point sources 200 are spaced the first distance S1 to the third distance S3 apart from one another.

The thicknesses of the thin film are greatest at right vertical directions of the respective point sources 200 and demonstrate a Gaussian distribution, which is, however, based upon simulation and the simulated values are obtained without consideration taken into an evaporating prevention plate of actual facility or interference of a driver.

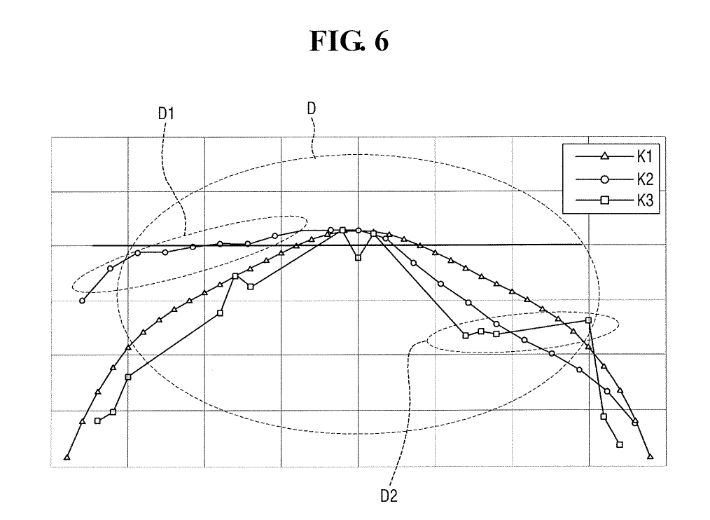

FIG. 6 is a graph illustrating comparison results of simulated values and actually measured values of thicknesses of thin films evaporated by the vapor evaporating device according to an embodiment of the present inventive concept. FIG. 6 is an enlarged view of a ‘D’ portion of FIG. 5, specifically illustrating actually measured values.

Referring to FIG. 6, K1 is a graphical representation based upon simulation. The vapor evaporating device may be tested at a device production site and may be disassembled and moved to an actually used position to then be reassembled. The actually measured value tested at the device production site is represented by K2 and the actually measured value obtained after being reassembled is represented by K3.

K1 is a graph indicating the ideal shape in which the thickness of the thin film closest to the point source 200 is greatest and gradually decreases in a Gaussian distribution. The shape represented by K1 is enlarged by scaling and may be an ideal shape in a predicted range of uniformity allowance. However, K2 and K3 may indicate unexpectedly measured values due to interference and a change in the assembling positions. That is to say, measured values D and D2, as shown in FIG. 6, may be unexpectedly produced.

When a cathode is deposited on the panel 10, it is important to deposit the cathode to a uniform thickness. However, uniformity in the thickness of the thin film may not be guaranteed due to the unexpectedly measured values. As the result, the thin film deposited on the panel 10 may have deteriorated quality.

Therefore, to correct such an error and maintain the uniformity in the thickness of a thin film, attempts to differentially consume materials of the plurality of point sources 200 have conventionally been made. The thin film deposited on one surface of the panel 10 is made to have a uniform thickness by varying deposition ratios of the respective point sources 200.

However, the differentially consuming of the materials of the plurality of point sources 200 may cause more serious problems. When a vapor evaporation material of one of the plurality of point sources 200 is consumed, the materials of the other point sources 200 should be deposited on a deposition preventing plate, requiring additional time.

Since different periods of time are required in cooling the respective point sources 200, there may be some point sources 200 still having considerable amounts of materials left, extending the periods of time required in cooling the point sources 200, which results in an increase in the maintenance time, thereby ultimately revealing inefficiency of a production line.

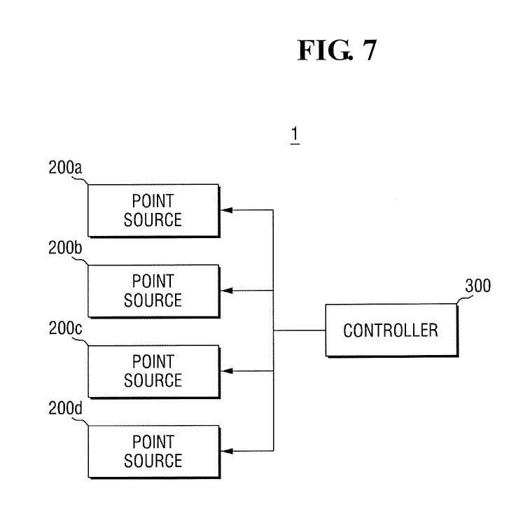

FIG. 7 is a block diagram illustrating the vapor evaporating device according to an embodiment of the present inventive concept.

Referring to FIG. 7, the vapor evaporating device 1 includes first to fourth point sources 200a, 200b, 200c, 200d and a controller 300.

As described above, the first to fourth point sources 200a, 200b, 200c, 200d may deposit the thin film on the panel 10.

The controller 300 may control positions of the first to fourth point sources 200a, 200b, 200c, 200d. The controller 300 may control distances between each of the first to fourth point sources 200a, 200b, 200c, 200d. Accordingly, the thickness of the thin film can be controlled by controlling the distances between each of the first to fourth point sources 200a, 200b, 200c, 200d, instead of applying differential consumption to differently measured values from the simulated values shown in FIG. 6.

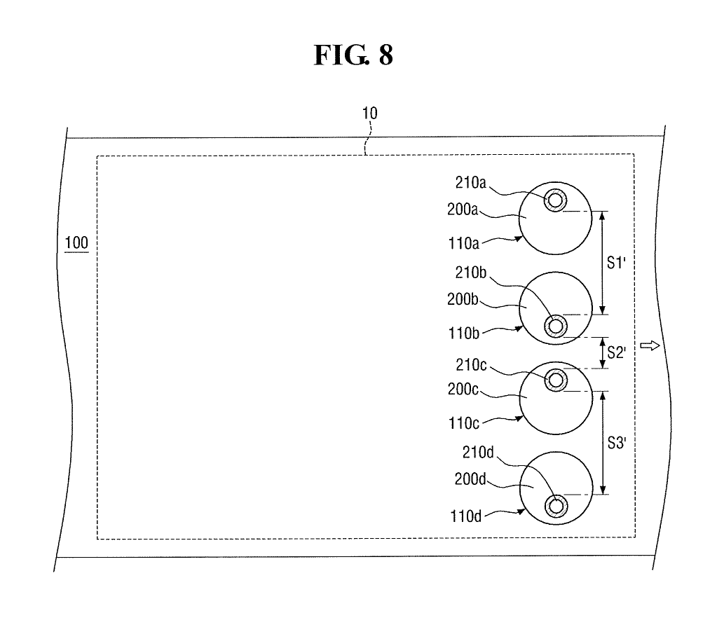

FIG. 8 is a plan view illustrating position movement of the vapor evaporating device according to an embodiment of the present inventive concept.

Referring to FIG. 8, the vapor evaporating device 1 according to an embodiment of the present inventive concept may adjust distances between each of the first point source 200a to the fourth point source 200d. The first distance S1 to the third distance S3 may be adjusted to a varied first distance S1′ to a varied third distance S3′. The thin film positioned with a decreased distance of each point source may have an increased thickness, while the thin film positioned with an increased distance of each point source may have a reduced thickness.

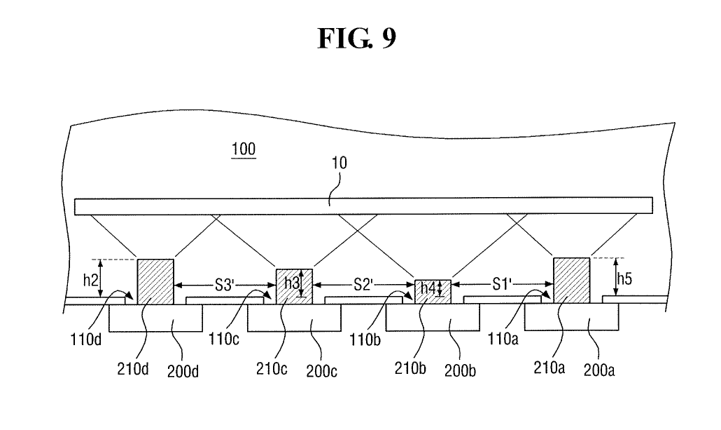

FIG. 9 is a front section view illustrating position movement of the vapor evaporating device according to an embodiment of the present inventive concept.

Referring to FIG. 9, in the vapor evaporating device 1 according to an embodiment of the present inventive concept, heights of first to fourth thermal evaporation modules 210a, 210b, 210c, 210d of the first to fourth point sources 200a, 200b, 200c, 200d may be adjusted. The heights of the first to fourth thermal evaporation modules 210a, 210b, 210c, 210d of the first to fourth point sources 200a, 200b, 200c, 200d, which are all the same, that is, a first height h1, are adjusted to be a second height h2 to a fifth height h5. The thin film positioned with an increased height of point source may have an increased thickness, while the thin film positioned with a reduced height of point source may have a reduced thickness.

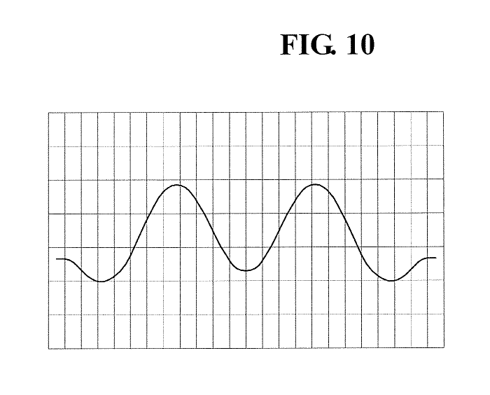

Hereinafter, position movement effects of the vapor evaporating device 1 according to an embodiment of the present inventive concept will be described with reference to FIGS. 10 to 12.

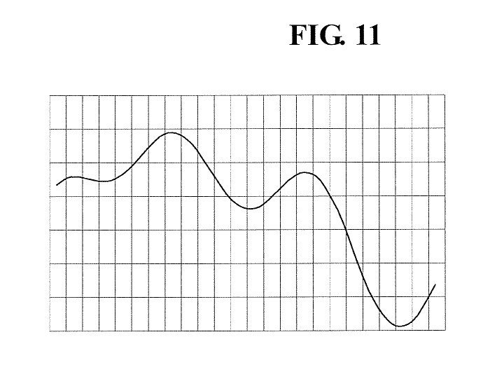

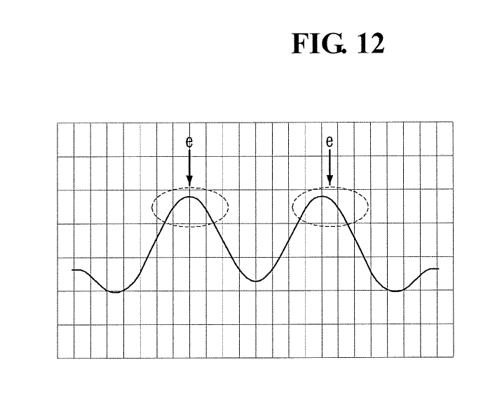

FIG. 10 is a graph illustrating a simulation result of thicknesses of a thin film evaporated using the vapor evaporating device according to an embodiment of the present inventive concept. FIG. 11 is a graph illustrating an actual measurement result of thicknesses of a thin film evaporated using the vapor evaporating device according to an embodiment of the present inventive concept. FIG. 12 is a graph illustrating a correction result of thicknesses of a thin film by position movement of the vapor evaporating device according to an embodiment of the present inventive concept.

Referring to FIG. 10, when the thicknesses of the thin film are simulated, they may be normal values showing the Gaussian distribution. That is to say, a profile of the thicknesses predicted and controlled according to the positions of the point sources 200 may be produced.

Referring to FIG. 11, there is a high probability of the actually measured values being different from the simulated values, which is because the thicknesses of the thin film may be changed according to various parameters, including positions of the point sources 200, interference, pressure, and so on, during actual measurement.

Referring to FIG. 12, the controller 300 controls the positions of the point sources 200, thereby correcting the thickness of the thin film to be equal to or similar to the simulated value. The term “correcting” used herein means forming the thin film having uniform thickness on the panel 10 newly subjected to an evaporating process, rather than changing the thickness of the thin film already formed. That is to say, portions indicated by ‘e’ in FIG. 12 are portions corrected by the point source 200 at a newly changed position.

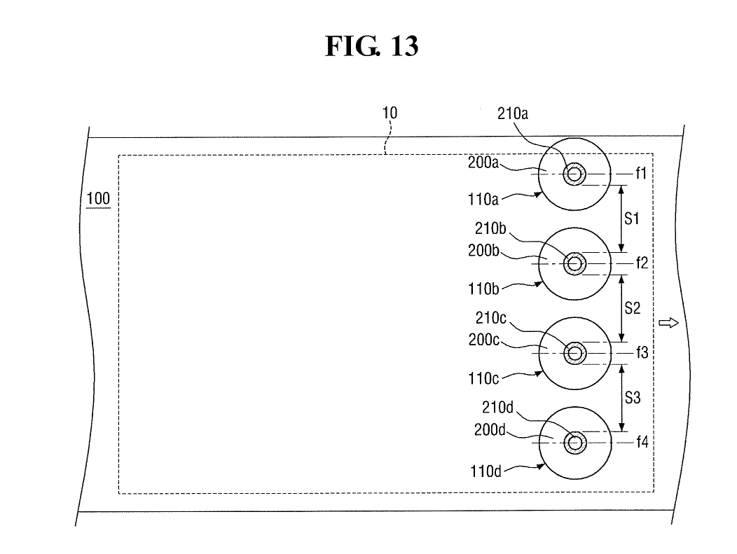

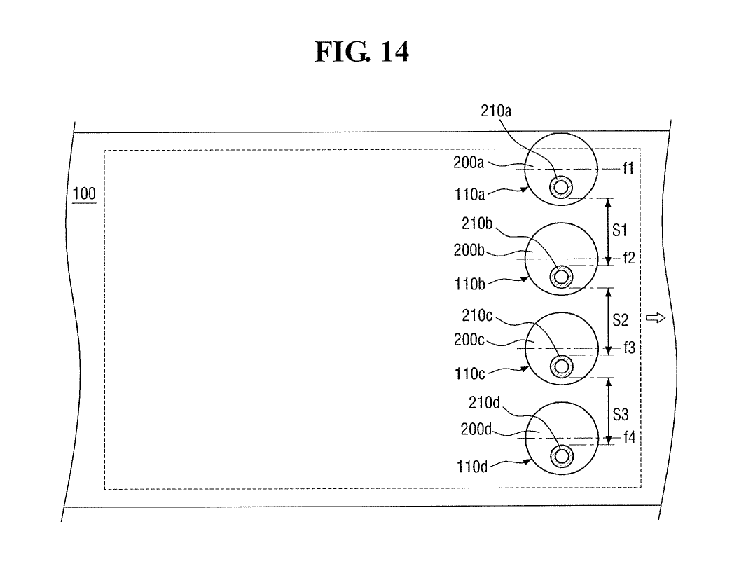

Hereinafter, a vapor evaporating device according to an embodiment of the present inventive concept will be described with reference to FIGS. 13 and 14. The same content as the previous embodiment will be briefly described or will not be given.

FIG. 13 is a plan view illustrating a vapor evaporating device (2) according to a second embodiment of the present inventive concept.

Referring to FIG. 13, in the vapor evaporating device 2 according to an embodiment of the present inventive concept a position of a panel 10 may be biased in a vacuum chamber 100 through a reassembling process. That is to say, the panel 10 may be slightly biased downwardly in FIG. 13.

In this case, the conventional vapor evaporating device is aligned by reattempting disassembling and reassembling processes, which, however, may increase the number of processes, including disassembling and reassembling additionally, undesirably resulting in serious waste of time and efficiency.

FIG. 14 is a plan view illustrating position movement of the vapor evaporating device 2 according to an embodiment of the present inventive concept.

Referring to FIG. 14, when the vapor evaporating device 2 according to an embodiment of the present inventive concept is misaligned, it may be realigned by moving the first to fourth point sources 200a, 200b, 200c, 200d by the same displacement.

Misalignment of the vapor evaporating device 2 can be corrected by moving the first to fourth thermal evaporation modules 210a, 210b, 210c, 210d of the first to fourth point sources 200a, 200b, 200c, 200d in the same direction while maintaining the distances of each of the first to fourth thermal evaporation modules 210a, 210b, 210c 210d at the first distance S1 to the third distance S3 without being changed.

The first to fourth point sources 200a, 200b, 200c, 200d are moved by the same displacement in the same direction from their original positions f1, f2, f3, f4, so that they are aligned with the panel 10 while maintaining their original distances without being changed.

The vapor evaporating device 2 according to an embodiment of the present inventive concept can correct its misalignment caused by an installation problem.

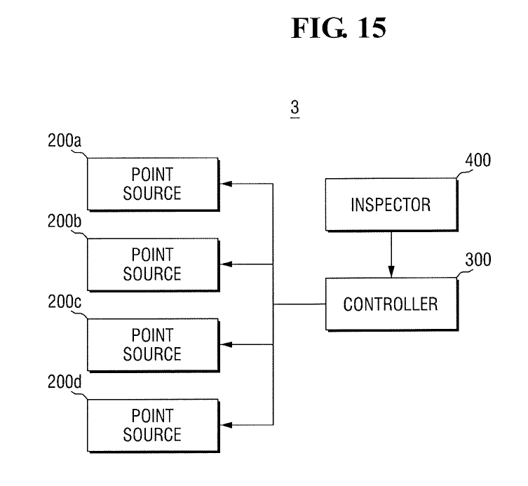

Hereinafter, a vapor evaporating device according to an embodiment of the present inventive concept will be described with reference to FIG. 15.

FIG. 15 is a block diagram illustrating a vapor evaporating device 3 according to an embodiment of the present inventive concept.

Referring to FIG. 15, the vapor evaporating device 3 according to an embodiment of the present inventive concept may further include an inspector 400.

The inspector 400 may inspect a thickness of an as-deposited thin film of a panel 10. Here, the inspector 400 may inspect the overall thickness of the thin film to detect a thickness profile.

The inspector 400 may transmit the detected profile to a controller 300. The inspector 400 may inspect the panel 10 having the thin film deposited thereon. The inspector 400 may preset a plurality of inspection points at the thin film. The inspector 400 may continuously inspect the profile of the thin film, but aspects of the present inventive concept are not limited thereto. Rather, the inspector 400 may discontinuously inspect the profile of the thin film at a fine interval.

The controller 300 may receive the profile of the thin film from the inspector 400. The controller 300 may readjust positions of the first to fourth point sources 200a, 200b, 200c, 200d based upon the profile of the thin film. To form a uniform thin film, distances between each of the first to fourth point sources 200a, 200b, 200c, 200d may be decreased or height of the first to fourth each point sources 200a, 200b, 200c, 200d may be increased at a position where the thin film has a small thickness on the profile received from the inspector 400.

Distances between each of the first to fourth point sources 200a, 200b, 200c, 200d may be increased or heights of each of the first to fourth point sources 200a, 200b, 200c, 200d may be reduced at a position where the thin film has a large thickness on the profile received from the inspector 400.

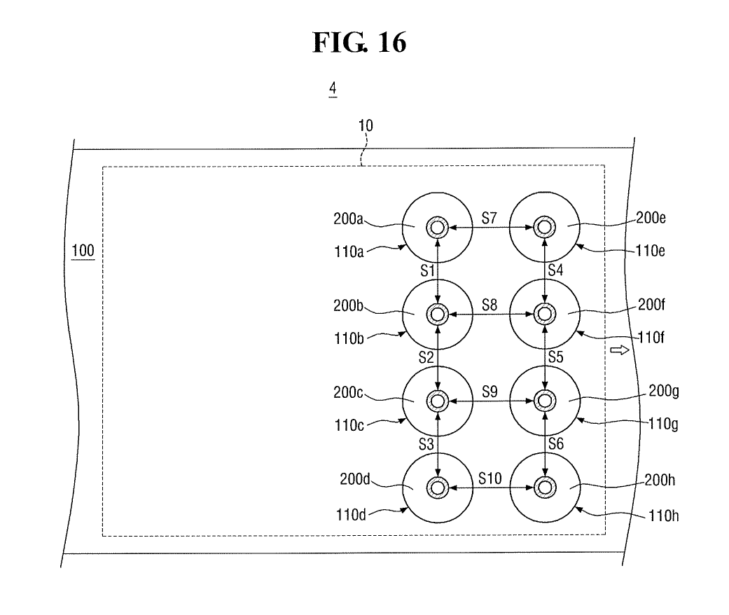

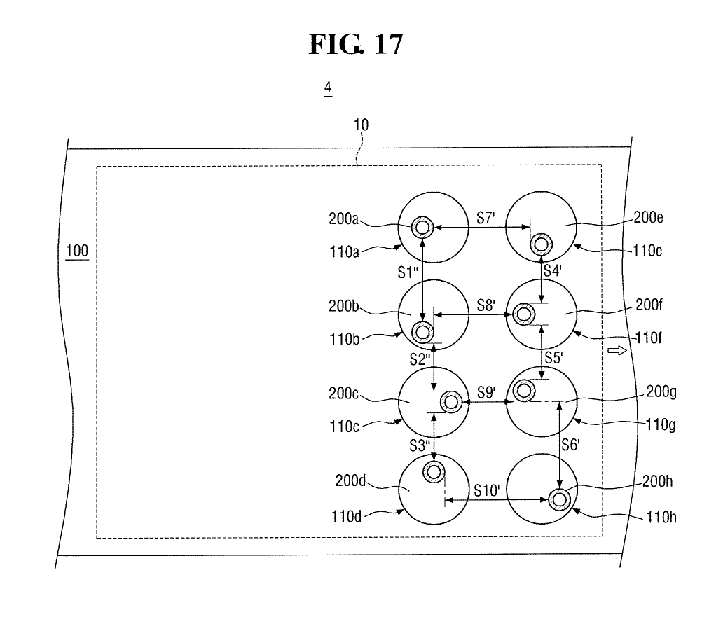

Hereinafter, a vapor evaporating device according to an embodiment of the present inventive concept will be described with reference to FIGS. 16 and 17.

FIG. 16 is a plan view illustrating a vapor evaporating device 4 according to an embodiment of the present inventive concept.

Referring to FIG. 16, in the vapor evaporating device 4 according to an embodiment of the present inventive concept, the vacuum chamber 100 may include source holes arranged in two columns. First to fourth source holes 110a, 110b, 110c 110d may form a column. Fifth to eighth source holes 110e, 110f, 110g 110h may form another column.

In FIG. 16, the source holes arranged in two columns are depicted, which is provided only for illustration. That is to say, the present inventive concept does not limit the number of columns of the source holes to that illustrated herein.

The point source 200 may be positioned to correspond to the source hole 110. That is to say, the first to fourth point sources 200a, 200b, 200c, 200d may form a column. In addition, fifth to eighth point sources 200e, 200f, 200g, 200h may form another column.

Since multiple point sources 200 are provided, they may be spaced apart from one another. The first thermal evaporation module 210a of the first point source 200a and the second thermal evaporation module 210b of the second point source 200b may be spaced a first distance S1 apart from each other. The second thermal evaporation module 210b of the second point source 200b and the third thermal evaporation module 210c of the third point source 200c may be spaced a second distance S2 apart from each other. The third thermal evaporation module 210c of the third point source 200c and the fourth thermal evaporation module 210d of the fourth point source 200d may be spaced a third distance S3 apart from each other.

The first distance S1 to the third distance S3 may be equal to or different from one another. A thin film having uniformity can be deposited when the first distance S1 to the third distance S3 are equal to each other. However, the first distance S1 to the third distance S3 may be adjusted according to various external parameters, which will later be described.

A fifth thermal evaporation module 210 of the fifth point source 200e and a sixth thermal evaporation module 210 of the sixth point source 200f may be spaced a fourth distance S4 apart from each other. A sixth thermal evaporation module 210 of the sixth point source 200f and a seventh thermal evaporation module 210 of the seventh point source 200g may be spaced a fifth distance S5 apart from each other. A seventh thermal evaporation module 210 of the seventh point source 200g and an eighth thermal evaporation module 210 of the eighth point source 200h may be spaced a sixth distance S6 apart from each other.

The fifth distance S5 to the sixth distance S6 may be equal to or different from one another. A thin film having uniformity can be deposited when the fifth distance S5 to the sixth distance S6 are equal to each other. However, the fifth distance S5 to the sixth distance S6 may be adjusted according to various external parameters.

In addition, the first thermal evaporation module 210a of the first point source 200a and the fifth thermal evaporation module 210 of the fifth point source 200e may be spaced a seventh distance S7 apart from each other. The second thermal evaporation module 210b of the second point source 200b and the sixth thermal evaporation module 210 of the sixth point source 200f may be spaced an eighth distance S8 apart from each other. The third thermal evaporation module 210c of the third point source 200c and the seventh thermal evaporation module 210 of the seventh point source 200g may be spaced a ninth distance S9 apart from each other. The fourth thermal evaporation module 210d of the fourth point source 200d and the eighth thermal evaporation module 210 of the eighth point source 200h may be spaced a tenth distance S10 apart from each other.

The seventh distance S7 to the tenth distance S10 may be equal to or different from one another. A thin film having uniformity can be deposited when the seventh distance S7 to the tenth distance S10 are equal to each other. However, the seventh distance S7 to the tenth distance S10 may be adjusted according to various external parameters.

FIG. 17 is a plan view illustrating position movement of the vapor evaporating device 4 according to an embodiment of the present inventive concept.

Referring to FIG. 17, the vapor evaporating device 4 according to an embodiment of the present inventive concept may adjust distances between each of the first point source 200a to the fourth point source 200d. That is to say, the first distance S1 to the third distance S3 may be adjusted to a readjusted first distance S1″ to a readjusted third distance S3″. The thin film positioned with a decreased distance of each point source may have an increased thickness, while the thin film positioned with an increased distance of each point source may have a reduced thickness.

The vapor evaporating device 4 according to an embodiment of the present inventive concept may adjust distances between each of the fourth point source 200d to the eighth point source 200h. That is to say, the fourth distance S4 to the sixth distance S6 may be adjusted to a readjusted fourth distance (S4′) to a readjusted sixth distance S6′. The thin film positioned with a decreased distance of each point source may have an increased thickness, while the thin film positioned of each point source with an increased distance may have a reduced thickness.

Further, the vapor evaporating device 4 according to an embodiment of the present inventive concept may adjust distances between each of the respective columns. That is to say, the seventh distance S7 to the tenth distance S10 may be adjusted to a readjusted seventh distance ST to a readjusted tenth distance S10′. The thin film positioned with a decreased distance of each point source may have an increased thickness, while the thin film positioned with an increased distance of each point source may have a reduced thickness.

Hereinafter, a vacuum evaporating method according to an embodiment of the present inventive concept will be described with reference to FIGS. 1 to 3, 8, 9, and 15 and 19.

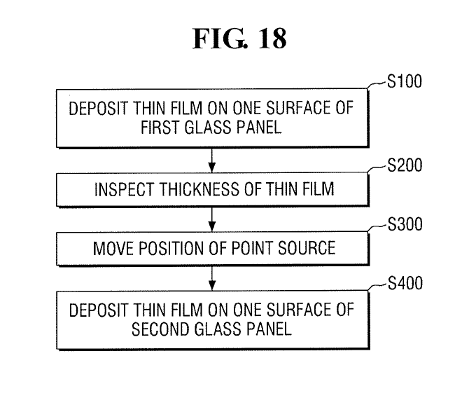

FIG. 18 is a flowchart illustrating a vacuum evaporating method according to an embodiment of the present inventive concept.

Referring to FIG. 18, a thin film is deposited on one surface of a first glass panel S100.

Referring to FIGS. 1 to 3, the vacuum chamber 100 may be a closed chamber isolated from the outside. That is to say, the vacuum chamber 100 may be a receiving space having an internal vacuum, unlike the ambient atmosphere. A vacuum pressure of the vacuum chamber 100 may be slightly higher than that of the universe. For example, the vacuum pressure of the vacuum chamber 100 may be approximately 10⁻⁵ Pa, but aspects of the present inventive concept are not limited thereto.

The first glass panel 10 may travel in one direction within the vacuum chamber 100. An organic material thin film or an inorganic material thin film may be deposited on the first glass panel 10 within the vacuum chamber 100. That is to say, the depositing of the organic material thin film or the inorganic material thin film may be performed under a vacuum condition.

The first glass panel 10 may be shaped of a plate having relatively thin lateral surfaces and opposite surfaces having a relatively wide area. The opposite surfaces having a relatively wide area may be rectangular, but aspects of the present inventive concept are not limited thereto. The first glass panel 10 may be used as a panel of a television or a display device.

The first glass panel 10 may have an organic material thin film deposited thereon in the vacuum chamber 100 to represent a color. Alternatively, after depositing the organic material thin film, a cathode thin film may be uniformly deposited. The cathode may include, for example, aluminum (Al).

The source hole 110 may be formed under the vacuum chamber 100, but aspects of the present inventive concept are not limited thereto. In an exemplary embodiment shown in FIG. 1, the source hole 110 is formed under the vacuum chamber 100, and when the panel 10 travels in one direction in a lying, the point source 200 to be described later may form a thin film on one surface, that is, bottom surface, of the panel 10 through thermal evaporation. However, the source hole 110 may be positioned on a lateral surface or a top surface of the vacuum chamber 100, rather than the bottom surface. In this case, the position of the first glass panel 10 may also vary. During the thermal evaporation, the point source 200 is generally positioned under the first glass panel 10.

The point source 200 may be positioned in the source hole 110. The source hole 110 may be an opening configured to allow the point source 200 to deposit a thin film on the panel 10. The point source 200 may be positioned in the source hole 110 in a state in which at least one of the point source 200 passes through the source hole 110, but aspects of the present inventive concept are not limited thereto. The point source 200 and the source hole 110 are not limited in view of vertical positions so long as the point source 200 can deposit a thin film on one surface of the first glass panel 10 through the source hole 110.

The source hole 110 may includes a plurality of source holes. The source hole 110 and the point source 200 may correspond to each other in a one-to-one relationship. That is to say, each of the plurality of point sources 200 may be positioned to correspond to one of the plurality of source holes 110. While the source hole 110 is an opening, to maintain the vacuum chamber 100 at a vacuum state, a device may be additionally required to maintain the vacuum state at a portion where the source hole 110 and the point source 200 are coupled to each other.

The point source 200 may deposit an organic or inorganic material thin film on the first glass panel 10 at its fixed position. As the first glass panel 10 travels in one direction, the point source 200 may entirely deposit a thin film on one surface of the first glass panel 10 at its fixed position.

The point source 200 may be positioned in the source hole 110. The source hole 110 may include a plurality of sources holes and the point source 200 may also include a plurality of point source so as to correspond thereto. That is to say, the point sources 200 and the source holes 110 may correspond to each other in a one-to-one relationship, but aspects of the present inventive concept are not limited thereto.

The point source 200 may deposit a thin film upwardly from a lower portion of the vacuum chamber 100 through the source hole 110. The thin film may be deposited on the bottom surface of the first glass panel 10, as shown. In view of the thermal evaporation principle in which a vapor evaporation material is heated and vaporized for evaporation, it is difficult to control a thickness of the thin film positioned on a top surface or a lateral surface, rather than the bottom surface, of the vacuum chamber 100. However, the position of the point source 200 is not limited.

The point source 200 may include the thermal evaporation module 210. The thermal evaporation module 210 contains the vapor evaporation material. The thermal evaporation module 210 may include a top opening to allow the heated and vaporized vapor evaporation material to be upwardly exhausted.

The source hole 110 includes a plurality of source holes, which may be aligned each other. That is to say, the source hole 110 may include the first source hole 110a to the fourth source hole 110d. The plurality of source holes 110 may be aligned in a direction perpendicular to a direction in which the first glass panel 10 travels. According to the alignment of the source holes 110, a thickness of the thin film deposited on one surface of the first glass panel 10 may be easily controlled.

In FIG. 2, the source hole 110 including 4 source holes is illustrated, which is, however, provided only for illustration. That is to say, there is no particular limit in the number of source holes 110.

The point sources 200 may be positioned in the source holes 110. The point sources 200 may correspond to the source holes 110 in a one-to-one relationship. Since the source holes 110 are aligned, the point sources 200 may also be aligned, as shown. However, the alignment of the point sources 200 may be modified in various manners, unlike the fixed alignment of the source holes 110.

The thermal evaporation module 210 of each of the plurality of point sources 200 may have a constant height. That is to say, as shown, each of the first to fourth thermal evaporation modules 210a, 210b, 210c 210d may have a first height h1. The first height h1 may mean a distance between the top surface of the thermal evaporation module 210 and the bottom surface of the vacuum chamber 100.

Referring to FIG. 3, all of the first thermal evaporation module 210a to the fourth thermal evaporation module 210d may have the same height, that is, the first height h1. However, the first height h1 may be readjusted according to various external parameters.

Referring again to FIG. 18, a thickness of the thin film deposited on the first glass panel 10 is inspected (S200).

Referring to FIG. 15, the inspector 400 may inspect the thickness of the as-deposited thin film of the first glass panel 10. Here, the inspector 400 may inspect the overall thickness of the thin film to detect a thickness profile.

The inspector 400 may transmit the detected profile to a controller 300. The inspector 400 may inspect the panel 10 having the thin film deposited thereon. The inspector 400 may preset a plurality of inspection points at the thin film. The inspector 400 may continuously inspect the profile of the thin film, but aspects of the present inventive concept are not limited thereto. Rather, the inspector 400 may discontinuously inspect the profile of the thin film at a fine interval.

Referring again to FIG. 18, a position of the point source is moved (S300).

Referring to FIGS. 8 and 9, distances between each of the first point source 200a to the fourth point source 200d may be adjusted. That is to say, the first distance S1 to the third distance S3 may be adjusted to the varied first distance S1′ to the varied third distance S3′. The thin film positioned with a decreased distance of each point source may have an increased thickness, while the thin film positioned with an increased distance of each point source may have a reduced thickness.

The heights of the first to fourth thermal evaporation modules 210a, 210b, 210c 210d of the first to fourth point sources 200a, 200b, 200c, 200d may be adjusted. That is to say, the heights of the first to fourth thermal evaporation modules 210a, 210b, 210c 210d of the first to fourth point sources 200a, 200b, 200c, 200d, which are all the same, that is, the first height h1, are adjusted to be the second height h2 to the fifth height h5. The thin film positioned with an increased height of point source may have an increased thickness, while the thin film positioned with a reduced height of point source may have a reduced thickness.

Referring again to FIG. 18, a thin film is deposited on one surface of a second glass panel (S400).

Referring to FIGS. 8 and 9, the thin film may be deposited on the second glass panel based upon the changed position. Accordingly, the second glass panel may obtain a profile having a more uniform, more accurate thin film.

While the present inventive concept has been particularly shown and described with reference to exemplary embodiments thereof, it will be understood by those of ordinary skill in the art that various changes in form and details may be made therein without departing from the spirit and scope of the present inventive concept as defined by the following claims. It is therefore desired that the present embodiments be considered in all respects as illustrative and not restrictive, reference being made to the appended claims rather than the foregoing description to indicate the scope of the invention.

What is claimed is:

1. A device for vacuum evaporating comprising:
a thermal evaporation module configured to generate vapor in a vacuum chamber through a circular opening by heating a vapor evaporation material accommodated therein;
a moving stage positioned in an atmospheric area separated from the vacuum chamber and configured to adjust a position of the thermal evaporation module under the thermal evaporation module; and
a sealing part combined with the thermal evaporation module to isolate the vacuum chamber and the atmospheric area from each other and configured to maintain a vacuum state of the vacuum chamber while surrounding the thermal evaporation module and configured to permit movement of the thermal evaporation module.

2. The device of claim 1, wherein the thermal evaporation module comprises:
a crucible that accommodates the vapor evaporation material and includes the circular opening;
a heater configured to heat the crucible from the outside of the crucible; and
a cooler surrounding the heater and configured to prevent heat derived from the heater from spreading.

3. The device of claim 1,
wherein the vacuum chamber comprises a source hole opened to allow at least a portion of the thermal evaporation module to pass therethrough to be positioned in the vacuum chamber, and
wherein the sealing part comprises:
a protruding disk protruding beyond an outer wall of the thermal evaporation module;
a bellows surrounding the thermal evaporation module between an edge outer wall of the source hole of the vacuum chamber and the protruding disk and configured to maintain a vacuum state of the thermal evaporation module while permitting position movement of the vacuum chamber; and
an o-ring configured to seal a portion between the bellows and the edge outer wall of the source hole or between the bellows and the protruding disk.

4. The device of claim 3,
wherein the source hole has a size larger than that of a horizontal section of the thermal evaporation module, and
wherein a horizontal movement range of the thermal evaporation module is limited by the size of the source hole.

5. The device of claim 1, wherein the moving stage is configured to move the thermal evaporation module in three directions orthogonal to one another.

6. The device of claim 1,
wherein the thermal evaporation module comprises first and second thermal evaporation modules separated from each other, and
wherein positions of the first and second thermal evaporation modules are configured to move independently.

7. A device for vacuum evaporating comprising:
a vacuum chamber configured to pass a glass panel and including a plurality of source holes;
a plurality of point sources configured to thermally evaporate an organic layer or an inorganic layer on one surface of the glass panel and configured to be movable; and
a sealing part positioned between the point sources and an outer wall of the vacuum chamber and configured to maintain the inside of the vacuum chamber at a vacuum state while permitting movement of the point sources.

8. The device of claim 7, wherein the plurality of source holes are aligned in a direction perpendicular to a traveling direction of the glass panel.

9. The device of claim 7, wherein each of the source holes has a larger size than a horizontal section of each of the point sources and a movement range of each of the point sources is confined by the size of the source hole.

10. The device of claim 7, wherein the point sources are used in depositing a cathode on one surface of the glass panel.

11. The device of claim 10,
wherein the glass panel comprises first and second glass panel configured to sequentially pass the vacuum chamber,
wherein the device further comprises a controller configured to readjust positions of the point sources based upon the uniformity in the thickness of the cathode deposited on the first glass panel, and
wherein the point sources are configured to uniformly deposit the cathode on one surface of the second glass panel while the second glass panel passes at the readjusted positions of the point sources.

12. The device of claim 10, wherein the plurality of point sources are configured to move in three directions orthogonal to one another to be aligned to uniformly deposit the cathode.

13. The device of claim 10, wherein the cathode comprises aluminum (Al).

14. The device of claim 7, wherein the source holes and the point sources correspond to each other in a one-to-one relationship.

15. The device of claim 7, wherein the point sources are configured to deposit an organic layer containing carbon on one surface of the glass panel.

16. The device of claim 7, wherein the sealing part comprises:
a protruding disk protruding beyond an outer wall of each of the point sources;
a bellows surrounding the thermal evaporation module between an edge outer wall of the vacuum chamber and the protruding disk and is configured to maintain a vacuum state of the thermal evaporation module while permitting position movement of the vacuum chamber; and
an o-ring configured to seal a portion between the bellows and the edge outer wall of the source hole or between the bellows and the protruding disk.

17. A device for vacuum evaporating comprising:
a vacuum chamber configured to move a panel in one direction;
a plurality of point sources positioned within the vacuum chamber and configured to thermally evaporate a thin film on one surface of the panel at fixed positions;
an inspector configured to inspect a thickness of the thin film; and
a controller configured to receive the thickness from the inspector and configured to readjust positions of the plurality of point sources.

18. The device of claim 17, wherein when the positions of the plurality of point sources are realigned, the plurality of point sources are moved by the same displacement.

19. The device of claim 17,
wherein the inspector is configured to inspect uniformity of the thin film, and
wherein the controller configured to readjust the positions of the plurality of point sources to deposit the thin film having uniformity in thickness.

20. The device of claim 17, wherein the controller is configured to receive information on a profile of the thin film and is configured to readjust the positions of the plurality of point sources to deposit the thin film having the same profile with the received profile.
